(19) United States
(12) Patent Application Publication
(10) Pub. No.: US 2023/0119426 A1
(43) Pub. Date: Apr. 20, 2023

(54) LIDAR DEVICE

(71) Applicant: SAMSUNG ELECTRONICS CO., LTD., Suwon-si (KR)

(72) Inventors: Yongchul CHO, Suwon-si (KR); Inoh HWANG, Seongnam-si (KR); Kyunghyun SON, Seongnam-si (KR)

(73) Assignee: SAMSUNG ELECTRONICS CO., LTD., Suwon-si (KR)

(21) Appl. No.: 17/573,300

(22) Filed: Jan. 11, 2022

(30) Foreign Application Priority Data
Oct. 20, 2021 (KR) 10-2021-0140493

(51) Int. Cl. G01S 7/4865; H01L 31/107; G01S 7/4863; G01S 17/89; G01S 7/481

(52) U.S. Cl. CPC G01S 7/4865; H01L 31/107; G01S 7/4863; G01S 17/89; G01S 7/481; G02B 5/04

(57) ABSTRACT

A laser induced light detection and ranging (LiDAR) device includes a light source configured to output light, a light detection array including a plurality of light detection elements configured to receive light that is output from the light source and reflected by an object and to convert the light into a corresponding electric signal, a lens configured to focus the light reflected by the object on the plurality of light detection elements, a prism provided between the lens and the light detection array, the prism being configured to split the light output from the lens and direct the light to be incident on the light detection array, and a processor configured to process the electrical signal, and obtain a time of flight (TOF) of the received light based on the processed electrical signal.

### CROSS-REFERENCE TO RELATED APPLICATION

This application is based on and claims priority under 35 U.S.C. § 119 to Korean Patent Application No. 10-2021-0140493, filed on Oct. 20, 2021, in the Korean Intellectual Property Office, the disclosure of which is incorporated by reference herein in its entirety.

### BACKGROUND

### 1. Field

Example embodiments of the present disclosure relate to light detection and ranging (LiDAR) devices.

### 2. Description of Related Art

Recently, a LiDAR sensor that measures the surroundings in three dimensions for driver assistance and autonomous driving of vehicle has been used. To this end, to measure a three-dimensional (3D) distance to a distant object within, for example, 300 meters, it is necessary to increase the light transmission output and improve the light reception efficiency of a measuring device. A light receiver of the related art includes a lens and a two-dimension (2D) light detection array, and requires application of a high reverse bias voltage between light detection elements. Accordingly, a dead zone of a certain width is required to prevent breakdown between the light detection elements. When light is incident on the dead zone, the light may not be received or detected by the light detection element, and accordingly, there is a problem in that the light reception efficiency is lowered.

### SUMMARY

One or more example embodiments provide LiDAR devices having a high light reception efficiency.

One or more example embodiments also provide LiDAR devices less influenced by a dead zone.

Additional aspects will be set forth in part in the description which follows and, in part, will be apparent from the description, or may be learned by practice of example embodiments.

According to an aspect of an example embodiment, there is provided a laser induced light detection and ranging (LiDAR) device including a light source configured to output light, a light detection array including a plurality of light detection elements configured to receive light that is output from the light source and reflected from an object and to convert the light into a corresponding electric signal, a lens configured to focus the light reflected from the object on the plurality of light detection elements, a prism provided between the lens and the light detection array, the prism being configured to split the light output from the lens and direct the light to be incident on the light detection array, and a processor configured to process the electrical signal, and obtain a time of flight (TOF) of the received light based on the processed electrical signal.

The prism may be a bi-prism or quad-prism.

The prism may be a hexahedron including at least one face having a trapezoid shape.

Two angles of a bottom side of the trapezoid shape may be 1 degree to 60 degrees, and a height of the prism may be 0.1 mm to 100 mm.

The prism may be spaced apart from the light detection array.

The prism may include two or more prisms, and the two or more prisms may form a bi-prism or a quad prism.

The prism may be provided to have a rotational phase of 0 degree to 90 degrees with respect to an optical axis of the lens.

The prism may be provided to have a rotational phase of 30 degrees to 60 degrees with respect to an optical axis of the lens.

The light reflected from the object may be received by at least two of the plurality of light detection elements.

Each of a first light detection element and a second light detection element adjacent to each other from among the plurality of light detection elements may be configured to receive a part of the split light, and the processor may be further configured to add electrical signals output by the first light detection element and the second light detection element.

The light detection array may include a first column and a second column adjacent to each other, at least one light detection element provided in each of the first column and the second column may be configured to receive a part of the split light, and the processor may be further configured to add electrical signals output by the at least one light detection element disposed in each of the first column and the second column.

The plurality of light detection elements may include at least one of an avalanche photodiode (APD) or a single photon avalanche diode (SPAD).

The plurality of light detection elements of the light detection array may be provided in an N*M array, where N and M are an integer greater than or equal to 1.

Pitches between adjacent light detection elements among the plurality of light detection elements of the light detection array may be 50 μm to 2,000 μm, and an area of a dead zone in the light detection array may be 5% to 40% of an area of the light detection array.

A lowest light reception efficiency of the LiDAR device may be greater than or equal to 30%.

The prism may be a prism array including a plurality of prism elements, and the plurality of prism elements may correspond one-to-one to the plurality of light detection elements.

At least one of the plurality of prism elements may have a shape of a frustum of a quadrangular pyramid cut along a plane perpendicular to an optical axis of the lens.

At least one of the plurality of prism elements may be provided to have an rotational phase of 30 degrees to 60 degrees with respect to an optical axis of the lens.

The prism array may be in contact with the light detection array.

According to another aspect of an example embodiment, there is provided an electronic device including a laser induced light detection and ranging (LiDAR) device, the LiDAR device including a light source configured to output light, a light detection array including a plurality of light detection elements configured to receive light that is output from the light source and reflected from an object and to convert the light into a corresponding electric signal, a lens configured to focus the light reflected from the object on the plurality of light detection elements, a prism provided between the lens and the light detection array, the prism being configured to split the light output from the lens and direct the light to be incident on the light detection array, and a processor configured to process the electrical signal, and obtain a time of flight (TOF) of the received light based on the processed electrical signal.

### BRIEF DESCRIPTION OF THE DRAWINGS

The above and/or other aspects, features, and advantages of certain example embodiments will be more apparent from the following description taken in conjunction with the accompanying drawings, in which:

FIG. 1A is a diagram illustrating a configuration of a light detection and ranging (LiDAR) device and a path of light output from the LiDAR device according to an example embodiment;

FIG. 1B is a diagram showing a schematic configuration of a LiDAR device according to an example embodiment;

FIGS. 2A and 2B are diagrams illustrating examples of signal summing areas of a light detection array of a LiDAR device according to an example embodiment;

FIG. 3A is a plan view illustrating light paths of first to fifth rays in a LiDAR device according to an example embodiment;

FIG. 3B is a cross-sectional view illustrating the light paths of the first to fifth rays of FIG. 3A;

FIG. 4 is a graph illustrating imaging locations of the first to fifth rays incident on a light detection array in the case of FIGS. 3A and 3B;

FIG. 5A is a diagram illustrating one surface of a prism disposed at 45 degrees with respect to a light axis;

FIG. 5B is a plan view illustrating light paths of first to sixth rays in a LiDAR device according to an example embodiment;

FIG. 5C is a cross-sectional view illustrating the light paths of the first to sixth rays of FIG. 5B;

FIG. 5D is a view illustrating a light path that appears after rotating the LiDAR device of FIG. 5B in a counterclockwise direction by 45 degrees with respect to the z-axis;

FIG. 6 is a graph illustrating locations of the first to sixth rays incident on a light detection array in the case of FIGS. 5A to 50,

FIG. 7 is a cross-sectional view illustrating a light path when 9 representative points are imaged in a LiDAR device according to an example embodiment;

FIG. 8A is a graph illustrating a result of splitting and forming 9 representative points on a light detection array in FIG. 7;

FIG. 8B illustrates a dead zone overlapped on the graph of FIG. 8A;

FIG. 9A is a diagram conceptually illustrating a configuration of a LiDAR device and a path of light output from the LiDAR device according to an example embodiment;

FIG. 9B is a diagram illustrating a configuration of a prism array of a LiDAR device according to an example embodiment;

FIG. 10A is a plan view illustrating light paths of first to fourth rays in a LiDAR device according to an example embodiment;

FIG. 10B is a cross-sectional view illustrating light paths of the first to fourth rays of FIG. 10A;

FIG. 11 is a graph illustrating imaging locations of the first to fourth rays incident on a light detection array in the case of FIGS. 10A and 10B;

FIG. 12 is a cross-sectional view illustrating a light path when 9 representative points are imaged in a LiDAR device according to an example embodiment;

FIG. 13A is a graph illustrating a result of splitting and forming 9 representative points on a light detection array in FIG. 12;

FIG. 13B illustrates a dead zone overlapped on the graph of FIG. 13A;

FIG. 14 is a perspective view illustrating an example of an electronic device to which LiDAR devices according to an example embodiment is applied; and

FIGS. 15 and 16 are diagrams of a side view and a plan view, respectively, illustrating examples of applying a LiDAR device according to an example embodiment to a vehicle.

### DETAILED DESCRIPTION

Reference will now be made in detail to example embodiments of which are illustrated in the accompanying drawings, wherein like reference numerals refer to like elements throughout. In this regard, the example embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, example embodiments will be described in detail with reference to the accompanying drawings. Example embodiments described below are merely examples and various modifications may be made therein. In the drawings, the same reference numerals represent the same elements and a size of each element may be exaggerated for clarity and convenience of description.

It will be understood that when one element is referred to as being “on” or “above” another element, the element may be on the other element in direct contact with the other element or without contacting the other element. It will be also understood that when one element is referred to as being “under” or “below” another element, the element may be under the other element, in direct contact with the other element, or below the other element without contacting the other element.

As used herein, the singular expressions are intended to include plural forms as well, unless the context clearly dictates otherwise. It will be understood that when an element is referred to as “including” another element, the element may further include other elements unless mentioned otherwise.

The term “the” and demonstratives similar thereto may be understood to include both singular and plural forms.

The meaning of “connection” may include not only a physical connection, but also an optical connection, an electrical connection, etc.

In addition, all terms indicating examples (e.g., etc.) are only for the purpose of describing technical ideas in detail, and thus the scope of the present disclosure is not limited by these terms unless limited by the claims.

The terms “first,” “second,” etc. may be used to describe various elements but the elements should not be limited by the terms. These terms are only used herein to distinguish one element from another element.

A height, depth, thickness, etc. may substantially be of the dimensional range or within an error range recognized by those skilled in the art.

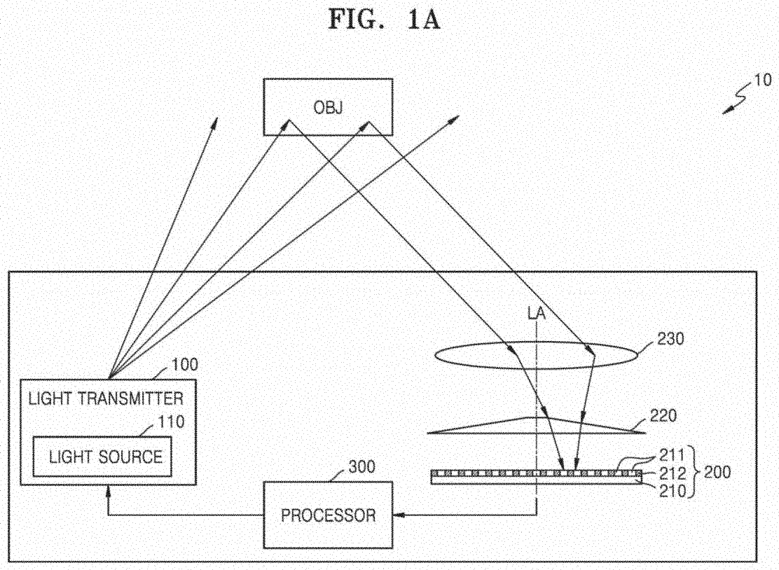

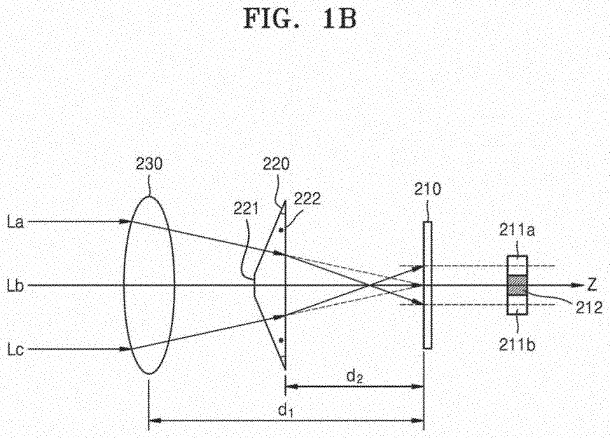

FIG. 1A is a diagram conceptually illustrating a configuration of a light detection and ranging (LiDAR) device 10 and a path of light output from the LiDAR device 10 according to an example embodiment. FIG. 1B is a diagram showing a configuration of the LiDAR device 10 according to an example embodiment.

The LiDAR device 10 according to an example embodiment may include a light source 110 outputting light, a light detection array 210 including a plurality of light detection elements 211 receiving light that is included in the light output from the light source 110 and reflected from an object (OBJ), and converting the received light into the corresponding an electrical signal, a lens 230 focusing the light reflected from the object on the plurality of light detection elements 211, a prism 220 disposed between the lens 230 and the light detection array 210, splitting (dispersing) the light output from the lens 230, and directing the split (dispersed) light to be incident on the light detection array 210, and a processor 300 processing the electrical signal after conversion by the light detection array 210, and calculating a time of flight (TOF) of the received light by using the processed electrical signal. The lens 230, the prism 220, and the light detection array 210 may be arranged in parallel along an optical axis LA. The LiDAR device 10 according to the example embodiment may include the prism 220 disposed between the lens 230 and the light detection element 211, thereby splitting the light reflected from the object, and accordingly, a light path of the light incident on a dead zone 212 between the light detection elements 211 may split so that the light may be dispersed and received by the one or more light detection elements 211. The processor 300 of the LiDAR device 10 according to an example embodiment may again sum electrical signals output by the dispersed and received light and map the object, thereby reducing an influence by the dead zone 212, and increasing light receiving efficiency of the LiDAR device 10.

The LiDAR device 10 according to an example embodiment may include the light source 110. The light source 110 may output light toward the object located outside the LiDAR device 10. When the object is located within a field of view (FoV) of the LiDAR device 10, the light may be reflected from the object. The light source 110 may be included, for example, in a light transmitter 100, and may be configured to output pulsed light at regular time intervals or continuously emitted continuous wave light under the control of the processor 300. In addition, the light source 110 may be configured to emit light in an infrared band, but is not limited thereto, may emit light having a greater wavelength than that of the light in the infrared band, and may emit light having a smaller wavelength than that of the light in the infrared band. For example, the light source 110 may use one of wavelengths of about 800 nm to about 2000 nm as an operating wavelength. For example, the light source 110 may be a laser diode (LD) light source 110 and may be a tunable laser diode configured to vary the wavelength of emitted light.

According to another example embodiment, the light source 110 may include a closed-curve waveguide resonator. In this example, the processor 300 may adjust a resonant wavelength of the closed-curve waveguide resonator, and accordingly, the wavelength of the light output from the light source 110 may be adjusted. For example, when the light source includes the closed-curve waveguide resonator, the light source 110 may further include a resonance element configured to vary the wavelength of light. The resonance element and the light source 110 may be used together to configure the variable wavelength light source 110, and the resonance element and the light source 110 may be integrated. For example, the resonance element may include a ring resonance element, and a heating element applying heat to the resonance element may be disposed around the ring resonance element. When the resonance element includes a first resonance element and a second resonance element, radii of the first resonance element and the second resonance element may be different from each other. However, the light source 110 of the LiDAR device 10 according to an example embodiment is not limited thereto, and various types of light sources 110 may be used.

The light transmitter 100 including the light source 110 may include a beam scanner that scans light or a beam steering element that steers light. The beam scanner may include a beam steering element, and may scan a beam at an angle in two directions. For example, the beam scanner may include a micro electro mechanical systems (MEMS) mirror that rotates in two directions, an MEMS mirror and a polygon mirror that rotate in one direction, and an optical phased array (OPA), etc. The beam scanner may steer the light so that steering directions are different according to the wavelength of the light output from the light source 110, but is not limited thereto. According to FIG. 1A, the direction in which the light is scanned or steered is shown in one direction, but a beam may be scanned at an angle in two directions. The scanning or steering direction may be, for example, a horizontal direction and/or a vertical direction. The light source 110 and the beam scanner may be integrally configured.

The LiDAR device 10 according to an example embodiment may include the light detection array 210. The light detection array 210 may include the plurality of light detection elements 211 that receive the light that is included in the light output from the light source 110 and reflected from the object, and convert the received light into the corresponding electrical signal. The light detection array 210 may be included in the light receiver 200 corresponding to the light transmitter 100. The light emitted toward the object from the light source 110 of the light transmitter 100 may be reflected by the object located within the FOV of the LiDAR device 10. A part of the reflected light may be reflected toward the light receiver 200 of the LiDAR device 10 and may be received by the light receiver 200. The reflected light may pass through each of the lens 230 and the prism 220 of the light receiver 200, and then may be received by at least one of the plurality of light detection elements 211 of the light detection array 210. The received light may be processed into an electrical signal by the processor 300 connected to the light receiver 200, and a distance to the object, a speed of the object, direction information, a shape of the object, etc. may be calculated through a TOF method.

The light detection array 210 may include the plurality of light detection elements 211. At least one of the plurality of light detection elements 211 may be an avalanche photodiode (APD) or a single photon avalanche diode (SPAD). Each of the plurality of light detection elements 211 may receive the light incident after being reflected from the object. The plurality of light detection elements 211 may be arranged in an N*M arrangement (wherein N and M are each an integer greater than or equal to 1) in the light detection array 210, each of the light detection elements 211 may be arranged in a grid direction, and the adjacent light detection elements 211 may be spaced apart from each other. Pitches between the light detection elements 211 may be, for example, about 50 μm to about 2000 μm. For example, pitches between the plurality of light detection elements 211 spaced in a vertical direction may be constant, and pitches between the plurality of light detection elements 211 spaced in a horizontal direction may be constant. However, embodiments are not limited thereto, and the spaced pitches in the vertical direction or the spaced pitches in the horizontal direction may not be constant.

A zone without a light detection element, that is, the dead zone 212, may be located between two adjacent light detection elements from among the plurality of light detection elements 211. When the light reflected from the object is incident on the dead zone 212, the light may not be received through the light detection array 210, and thus light reception efficiency may be lowered. Since the APD or the SPAD requires a reverse bias voltage greater than or equal to a certain amount so as to amplify reception sensitivity, the dead zone 212 with a certain width or more may be inevitably disposed between the light detection elements 211. For example, the dead zone 212 may occupy an area of about 5% to 40% of the light detection array 210. For example, the dead zone 212 may occupy an area of about 10% to 20% of the light detection array 210.

The LiDAR device 10 according to an example embodiment may include the lens 230 focusing the light reflected from the object on the light detection array 210. Referring to FIG. 1B, a distance d₁ between the lens 230 and the light detection array 210 may correspond to a focal length of the lens 230. However, embodiments are not limited thereto, and the distance d₁ may be changed in consideration of the disposition of the prism 220. The lens 230 may be a convex lens to focus the received light on the light detection array 210.

The LiDAR device 10 according to an example embodiment may further include the prism 220 between the lens 230 and the light detection array 210. The prism 220 may be spaced apart from the light detection array 210 by a certain distance d₂. However, embodiments are not limited thereto, and the prism 220 may be disposed in contact with the light detection array 210. The prism 220 may split the light by changing a propagation angle and a light path of the light passing through the lens 230. The split light may be incident on the at least one light detection element 211 through the prism 220, and accordingly, the light may be dispersed and received. For example, a point where the reflected light passing through the lens 230 is focused on the light detection array 210 may be the dead zone 212. In this example, when there is no prism 220, the corresponding light may not be received by the light detection array 210. When the prism 220 is disposed between the lens 230 and the light detection array 210, like the LiDAR device 10 according to an example embodiment, a part of the light may be changed by the prism 220 in the propagation angle and the light path, and may be split, and a part of the split light may be incident on the dead zone 212 of the light detection array 210, but a part of the remaining split light may be incident on at least one of the plurality of light detection elements 211 and received. For example, the prism 220 may split the light incident on the dead zone 212 and make the split light incident on a light receivable zone. The prism 220 of the LiDAR device 10 according to an example embodiment may reduce or prevent a decrease in the light reception efficiency due to the dead zone 212.

Referring to FIG. 1B, a first light La, a second light Lb, and a third light Lc may pass through the lens 230 and then be focused on the light detection array 210 toward the dead zone 212. After passing through the lens 230, the first light La, the second light Lb, and the third light Lc pass through the prism 220 so that the light path may be changed, and accordingly, the first light La, the second light Lb, and the third light Lc may be split and incident on the light detection array 210. When there is no prism 220, the first light La, the second light Lb, and the third light Lc may be focused and incident on the dead zone 212 and not received by the light detection array 210. Whereas, the LiDAR device 10 according to an example embodiment may include the prism 220 splitting the light so that the first light La, the second light Lb, and the third light Lc may be respectively focused and incident on a second light detection element 211b, the dead zone 212, and a first light detection element 211a. For example, the light may be dispersed and received by at least one of the plurality of light detection elements 211, thereby reducing or preventing the decrease in the light reception efficiency due to the dead zone 212, and improving the light reception efficiency.

The prism 220 may be, for example, a bi-prism or a quad-prism. The prism 220 may be, for example, a hexahedron in which at least one face of the prism 220 is a trapezoid. The prism 220 may be, for example, a hexahedron in which at least one cross-section parallel to an optical axis of the lens 230 is a trapezoid or includes a trapezoidal portion. In the example of the bi-prism, the hexahedron may have two trapezoidal faces, and the remaining faces may be rectangular. In the example of the quad-prism, the hexahedron may have four trapezoidal faces, and the remaining faces may be rectangular or square. The trapezoidal face may have two equal angles, a first surface 221 of the rectangular faces or a square faces may be disposed to face the lens 230, and a second face 222 of the rectangular faces or the square faces may be disposed to face the light detection array 210. An area of the first face 221 may be smaller than an area of the second face 222. However, embodiments are not limited thereto, and the bi-prism may be a hexahedron including two isosceles triangular faces. However, when the prism 220 is manufactured, a shape having a flat trapezoidal face may be appropriate rather than an isosceles triangle due to the characteristics of a material (e.g., glass) included in the prism 220. In addition, a flat trapezoid shape may be appropriate so as to prevent light from diffracting at a vertex (apex) other than vertices of two equal angles of an isosceles triangle. For example, a shape of a top view of the bi-prism may be a trapezoidal shape. In this example, the bi-prism may be disposed at 0 degree with respect to the optical axis of the lens 230. According to another example embodiment, the bi-prism may be disposed at 0 degree with respect to the optical axis of the lens 230 based on a direction in which the first face 221 or the second face 222 of the bi-prism is arranged. When the bi-prism is disposed at 0 degree with respect to the optical axis, light may be split in a direction of summation of components that are not parallel to the optical axis in an inclination direction of two inclined faces of the bi-prism facing the lens 230. For example, the bi-prism may be disposed to have a rotational phase in a counterclockwise direction with respect to the optical axis. The bi-prism may be disposed to have a rotational phase of 90 degrees in the counterclockwise direction with respect to the optical axis, and in this example, a shape of a side view of the bi-prism may be a trapezoidal shape. When the bi-prism is disposed at 90 degrees with respect to the optical axis, the light may be split in the direction of the summation of components that are not parallel to the optical axis in the inclination direction of the two inclined faces of the bi-prism facing the lens 230, in which example, the direction in which the light is split may be perpendicular to a direction in which the bi-prism is disposed at 0 degree with respect to the light axis. According to another example embodiment, the bi-prism may be disposed to have a rotational phase of 30 to 60 degrees with respect to the light axis, which may be appropriately selected according to the arrangement direction of the light detection array 210. For example, when the light detection array 210 is arranged in a grid by using the X-axis direction as a vertical direction and the Y-axis direction as a horizontal direction, the dead zone 212 may also be arranged in the grid in the vertical and horizontal directions. In this example, in order to reduce a ratio of light incident on the dead zone 212, the bi-prism may be disposed to have a rotational phase of, for example, about 30 degrees to about 60 degrees by using the Z-axis as a rotation axis. For example, the bi-prism may be disposed to be rotated by using the Z-axis as the rotation axis to form an angle of about 45 degrees with the X-axis.

The prism 220 may be, for example, a hexahedron in which at least one face of the prism 220 is a trapezoid. In the example of the bi-prism, the hexahedron may have two trapezoidal faces, and the remaining faces may be rectangular. In the example of the quad-prism, the hexahedron may have four trapezoidal faces, and the remaining faces may be square.

The prism 220 may be the quad-prism, and the quad-prism may be a hexahedron having four trapezoidal faces and two rectangular faces. Two of the four faces may have the same first trapezoidal shape, and the other two of the four trapezoidal faces may have the same second trapezoidal shape. The first trapezoid and the second trapezoid may have the same height. The first trapezoid and the second trapezoid may be the same trapezoid, and in this example, the other two faces of the hexahedron may be square. The first trapezoid and the second trapezoid may be different trapezoids, and in this example, the other two cross-sections of the hexahedron may be rectangular. When at least one of upper and lower sides of the first trapezoid and the second trapezoid is the same, at least one of the other two faces of the hexahedron may be square. Two angles included in each of the first trapezoid and the second trapezoid may be the same, and the first face 221 of two rectangular faces of the quad-prism may be disposed to face the lens 230, and the second face 222 of the two rectangular faces of the quad-prism may be disposed to face the light detection array 210. The first face 221 may have a smaller area than the second face 222. The quad-prism may have a pyramidal or quadrangular pyramid shape including four equal isosceles triangular faces, or may have a quadrangular truncated pyramid shape including four equal trapezoidal faces. A shape of a frustum of a quadrangular pyramid including four equal trapezoidal faces may mean a pyramid shape in which a central vertex (apex) is cut along a plane perpendicular to the optical axis. The quadrangular truncated pyramid shape may include the first face 221 in which a cut part is a flat plane. The quad prism, like the bi-prism described above, may be disposed to be rotated by 0 degree to about 90 degrees with respect to the optical axis. When a top view of the quad-prism is trapezoidal, and when the quad-prism is arranged at 0 degree, in this example, the quad-prism may disperse the incident light in a cross direction in the vertical and horizontal directions. When the quad-prism is disposed at 45 degrees with respect to the optical axis, the light incident on the quad-prism may disperse the incident light in the cross direction including a 45 degree diagonal direction with respect to the horizontal or vertical direction.

The trapezoidal face of the bi-prism described above is not limited to the trapezoidal shape, but may be a face including a protrusion in the trapezoid shape. In addition, the shape of the prism 220 is not limited to the bi-prism and quad-prism described above, and the prism 220 is enough to have a shape configured to disperse light.

A thickness of the prism 220 included in the LiDAR device 10 according to an example embodiment may be about 0.1 mm to about 100 mm. In addition, the prism 220 may be spaced apart from the light detection array 210 by about 2 mm to about 4 mm. For example, when the prism 220 is the bi-prism or the quad prism, the size of the same two angles included in the trapezoidal face of the prism 220 may be about 1 degree to about 60 degrees.

The prism 220 included in the LiDAR device 10 according to an example embodiment may include two or more prisms, and the two or more prisms may form the above-described bi-prism or quad prism.

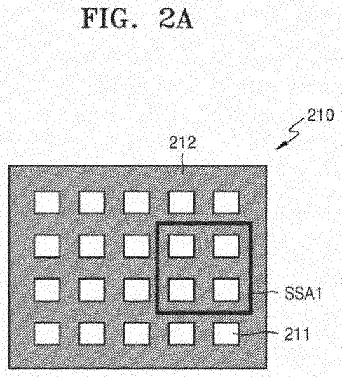

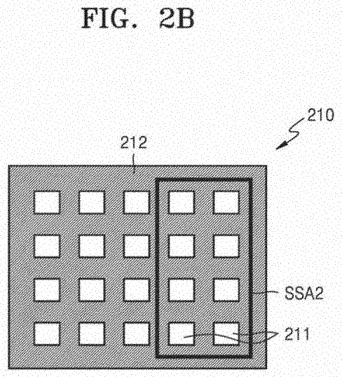

FIGS. 2A and 2B are diagrams illustrating examples of signal summing areas SSA1 and SSA2 of the light detection array 210 of the LiDAR device 10 according to an example embodiment.

Light reflected from an object by the above-described prism 220 may be dispersed and received in the light detection array 210. The signal summing areas SSA1 and SSA2 may be set in the plurality of light detection elements 211 of the light detection array 210, in order for the processor 300 to again sum and process electrical signals output by the dispersed and received light. The electrical signals that are output by the light dispersed and received in the light detection elements 211 included in the same signal summing areas SSA1 and SSA2 may be summed and processed by the processor 300. The light detection array 210 may include the plurality of signal summing areas SSA1 and SSA2.

For example, a first light detection element and a second light detection element adjacent to each other from among the plurality of light detection elements 211 may constitute the signal summing area SSA1. The first light detection element and the second light detection element may be regions adjacent to each other vertically or horizontally, or may be regions diagonally adjacent to each other at 45 degrees. Grouping of the adjacent light detection elements 211 into the signal summing area SSA1 may be determined according to an angle (rotational phase) of the prism 220, but embodiments are not limited thereto. The adjacent light detection elements 211 may be arbitrarily selected. Each of the first light detection element and the second light detection element of the signal summing area SSA1 may receive a part of the dispersed light, and the processor 300 may sum the part of light received by the first light detection element and the part of light received by the second detection element. For example, when a part of the light is received only by the first light detection element and a part of the light is not received by the second light detection element, the processor 300 may signal process only the part of light received by the first light detection element and may not separately perform summation. In the above example, two light detection elements are set as the signal summing area SSA1, but three or more light detection elements may be set as the signal summing area SSA1.

For example, when the plurality of light detection elements 211 of the light detection array 210 are arranged in an N*M array, the plurality of light detection elements 211 may be divided into M columns. A first column and a second column of the light detection array 210 that are adjacent to each other may constitute the signal summing area SSA2. However, embodiments are not limited thereto, and the plurality of light detection elements 211 may be divided into N rows so that a first row and a second row may constitute the signal summing area SSA2, and a first diagonal column and a second diagonal column may constitute the signal summing area SSA2 Setting of the signal summing area SSA2 may be determined according to the angle (rotational phase) of the prism 220. At least one light detection element disposed in the first column and the second column from among the plurality of light detection elements 211 may receive a part of the split light. For example, each of the first light detection element and the second light detection element respectively disposed in the first column and the second column may receive a part of the split light, and the processor 300 may sum an electrical signal output by the part of light received by the first light detection element and an electrical signal output by the part of light received by the second detection element. For example, when a part of the light is received only by the first light detection element and a part of the light is not received by the second light detection element, the processor 300 may signal process only the electrical signal output by the part of light received by the first light detection element and may not separately perform summation. In the above example, two columns are set as the signal summing area SSA2, but three or more columns may be set as the signal summing area SSA2.

The processor 300 of the LiDAR device 10 according to an example embodiment may process the electrical signal by the light received by the light detection array 210, and calculate a TOF of the received light by using the processed electrical signal. For example, the processor 300 may compute and calculate a distance to an object interacting with the light, a speed of the object, a moving direction of the object, etc. through a TOF method. The processor 300 of the LiDAR device 10 according to an example embodiment may calculate distances to objects located within a FOV of the LiDAR device 10, thereby mapping a space covered by the FOV and objects located in the space. In addition, the processor 300 may sum the electrical signals output by the light received by the light detection element of the signal summing areas SSA1 and SSA2 and process the signal.

Next, several examples of operation of the LiDAR device 10 according to an example embodiment will be described.

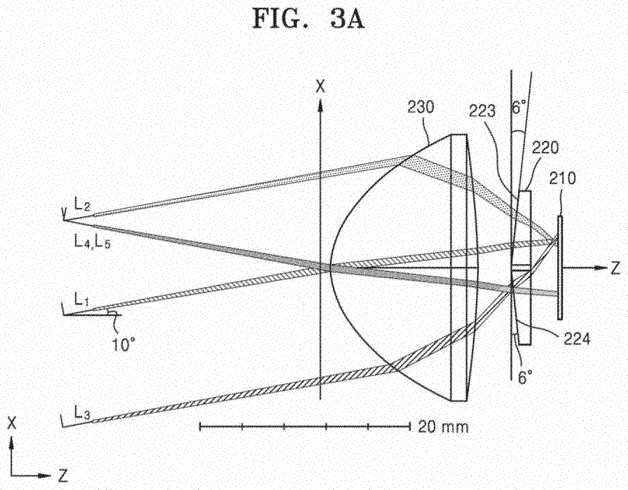

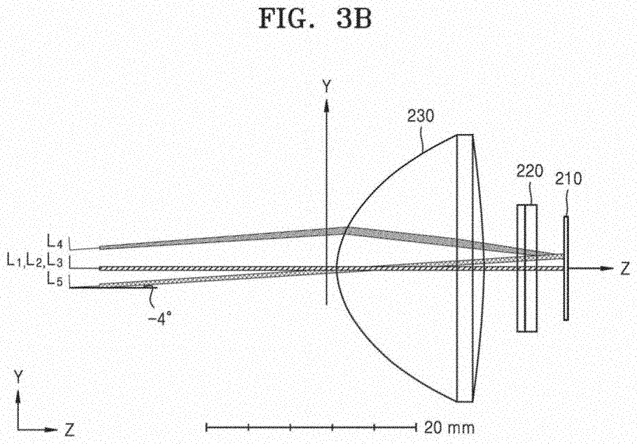

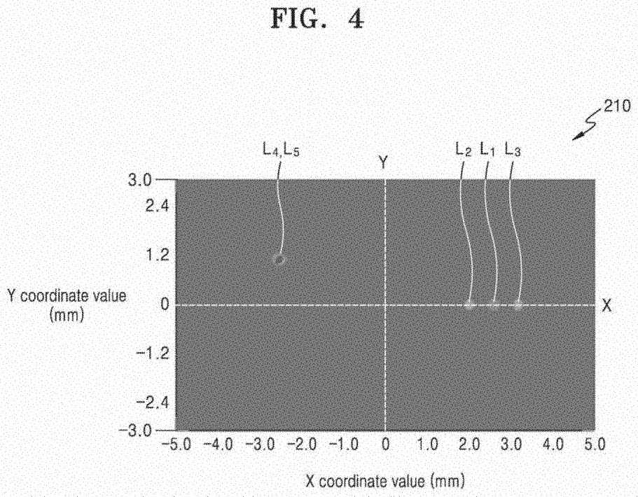

FIG. 3A is a plan view illustrating light paths of first to fifth rays L1 to L5 in the LiDAR device 10 according to an example embodiment. FIG. 3B is a cross-sectional view schematically illustrating the light paths of the first to fifth rays L1 to L5 of FIG. 3A. FIG. 4 is a graph illustrating imaging locations of the first to fifth rays L1 to L5 incident on the light detection array 210 in the example of FIGS. 3A and 3B.

According to FIG. 3A, the prism 220 included in the LiDAR device 10 according to an embodiment may have two inclined faces 223 and 224 rotated about +6 degrees and −6 degrees, respectively, about Y-axis as a rotation axis. The two inclined faces 223 and 224 of the prism 220 may be disposed to face the lens 230, and have inclination angles of about +6 degrees and about −6 degrees, respectively, with respect to X-axis. A face of the prism 220 including a trapezoid or trapezoidal protrusion may be perpendicular to the Y-axis, and in this example, the prism 220 may be rotated by 0 degree by using the optical axis (Z-axis) as the rotation axis. For example, the prism 220 may have a thickness of about 2 mm. Here, the thickness is included in a line parallel to an optical axis direction, and may mean the maximum distance between two points of the prism 220 on a line parallel to an optical axis direction.

According to FIG. 3A, the first ray L1, the second ray L2, and the third ray L3 may be spaced apart from each other by a certain distance in the X-axis direction, respectively, and may be inclined at an angle of 10 degrees in a counterclockwise direction by using the Y-axis direction as the rotation axis and incident on the lens 230. According to FIG. 3B, the first ray L1, the second ray L2, and the third ray L3 may not be spaced apart from each other in the Y-axis direction. The first ray L1, the second ray L2, and the third ray L3 may be reflected from the same object. In FIG. 3A, the first ray L1 and the second ray L2 may pass through the inclined face 223 of the prism 220, and the third ray L3 may pass through the inclined face 224 of the prism 220. The first ray L1, the second ray L2, and the third ray L3 may be split in the X-axis direction, which is a direction of summation of components that are not parallel to the Z-axis, among the inclination directions of the two inclined faces 223 and 224 of the prism 220, and imaged at different locations. In other words, because the prism 220 has the inclined faces 223 and 224 inclined by about +6 degrees and −6 degrees, respectively, by using the Y-axis as the rotation axis, as shown in FIG. 4, the first ray L1, the second ray L2, and the third ray L3 may be split along the X-axis and imaged at different locations.

According to FIG. 3A, the fourth ray L4 and the fifth ray L5 may not be spaced apart from each other in the X-axis direction. According to FIG. 3B, the fourth ray L4 and the fifth ray L5 may be spaced apart from each other by a certain distance in the Y-axis direction, and may be inclined at an angle of −4 degrees in a counterclockwise direction by using the X-axis direction as the rotation axis and incident on the lens 230. The fourth ray L4 and the fifth ray L5 may be reflected from the same object. In FIG. 3A, the fourth ray L4 and the fifth ray L5 may pass through the same inclined face 224 of the prism 220, and accordingly, as shown in FIG. 4, the fourth ray L4 and the fifth ray L5 reflected from the same object may be imaged on the light detection array 210 as a single point. However, embodiments are not limited thereto, and light paths of the fourth ray L4 and the fifth ray L5 may be changed by the prism 220 so that the fourth ray L4 and the fifth ray L5 are spaced part from each other in the Y-axis and imaged.

As described above, when the prism 220 has an inclined face rotated or inclined by using the Y-axis as the rotation axis, the light reflected from the object may be split into two or more points in the X direction and imaged on the OPA. In this example, a decrease in light reception efficiency due to light incident on the dead zone 212 having a certain width in the X direction and extending in the Y-axis may be reduced or prevented.

In the LiDAR device 10 according to an example embodiment described with reference to FIGS. 3A to 4, the prism 220 may be disposed at a rotational phase of 0 degree with respect to the optical axis so that the light may be split in the X-axis direction, but embodiments are not limited thereto. When the prism 220 is disposed at a rotational phase of 90 degrees with respect to the optical axis, the light may be split in the Y-axis direction. In this example, a decrease in light reception efficiency due to light incident on the dead zone 212 having a certain width in the Y direction and extending in the X-axis may be reduced or prevented.

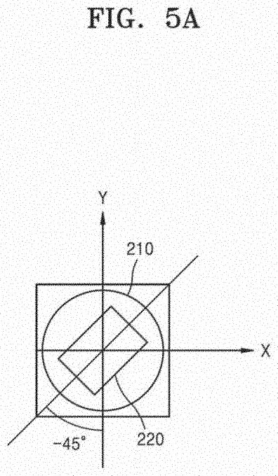

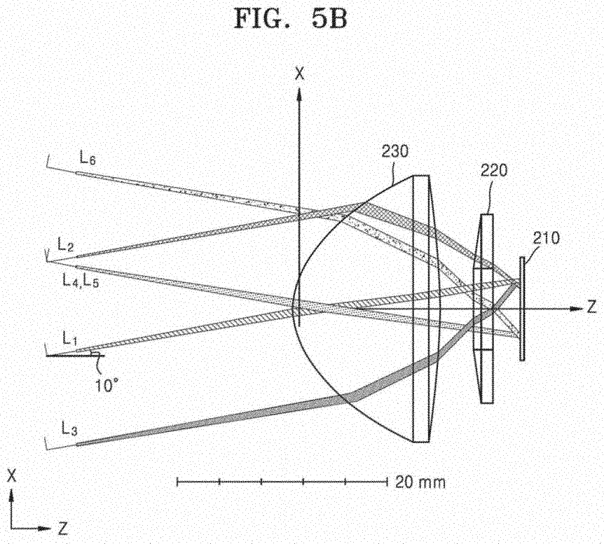

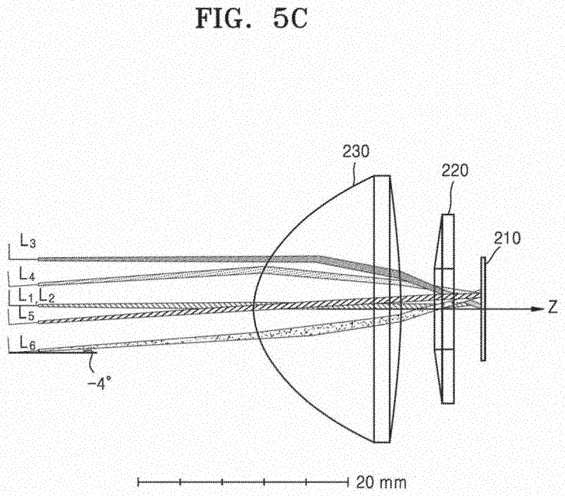

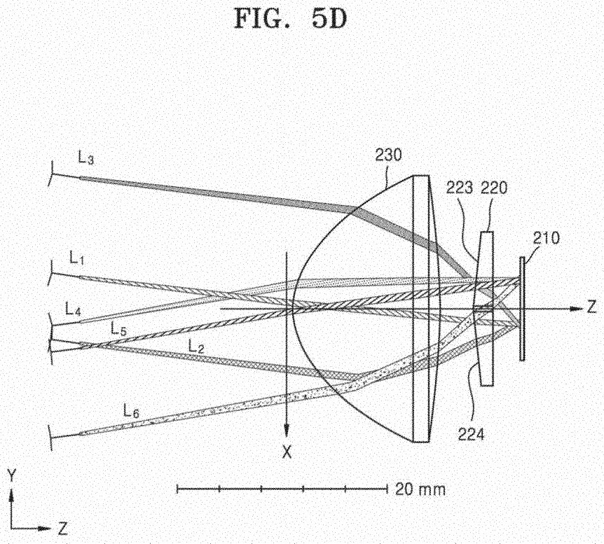

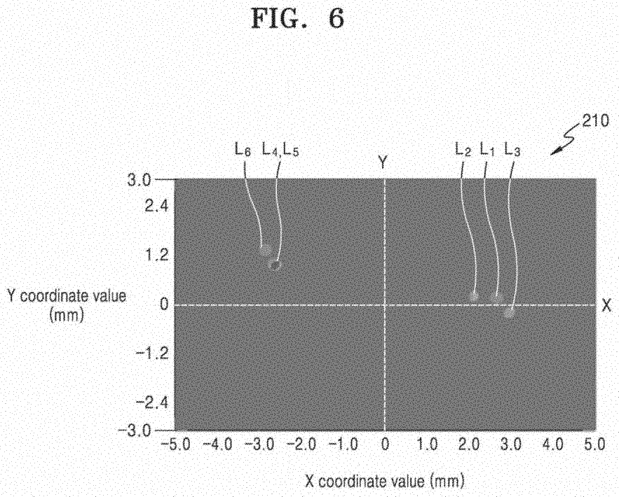

FIG. 5A is a diagram illustrating a prism disposed at 45 degrees with respect to an optical axis, and FIG. 5B is a plan view illustrating light paths of the first to sixth rays L1 to L5 in the LiDAR device 10 according to an embodiment. FIG. 5C is a cross-sectional view illustrating the light paths of the first to sixth rays L1 to L5 of FIG. 5B. FIG. 5D is a view illustrating a light path that appears after rotating the LiDAR device 10 of FIG. 5B in a counterclockwise direction by 45 degrees with respect to the z-axis. FIG. 6 is a graph illustrating locations of the first to sixth rays L1 to L6 incident on a light detection array in the example of FIGS. 5A to 5C.

According to FIG. 5A, the prism 220 included in the LiDAR device 10 according to an example embodiment may be rotated by −45 degrees by using the optical axis as a rotation axis. The prism 220 of FIGS. 5A to 5D may be arranged such that the prism 220 of FIGS. 3A and 3B is rotated by −45 degrees by using the light axis as the rotation axis.

According to FIG. 5B, the first ray L1, the second ray L2, and the third ray L3 may be incident spaced apart from each other by a certain distance in the X-axis direction and may be inclined at an angle of 10 degrees in the counterclockwise direction by using the Y-axis direction as the rotation axis and incident on the lens 230. According to FIG. 5C, the first ray L1 and the second ray L2 may not be spaced apart from each other in the Y-axis direction, and may be incident spaced apart from each other by a certain distance in the Y-axis direction. The first ray L1, the second ray L2, and the third ray L3 may be reflected from the same object. In FIG. 5D, the first ray L1 and the second ray L2 may pass through one inclined face 224 of the prism 220, and the third ray L3 may pass through the other inclined face 224 of the prism 220. Referring to FIG. 6, at least two of the first ray L1, the second ray L2, and the third ray L3 reflected from the same object may be split and imaged at different locations. In this example, the first ray L1 and the second ray L2 may be split in the x-axis direction, and the first ray L1 and the third ray L3 may be split in a diagonal direction of 45 degrees. In addition, the second light ray L2 and the third light ray L3 may be split in the diagonal direction. Because the first ray L1 and the second ray L2 are incident spaced apart from each other in the X-axis direction and pass through the same inclined face 224 of the prism 220, there is no factor in a change in the light path with respect to the Y-axis, and thus the first ray L1 and the second ray L2 may be split in the X-axis direction and imaged, whereas, because the first ray L1 and the third ray L3 are incident spaced apart from each other in the X-axis direction and the Y-axis direction, and pass through different inclined faces 224 and 223 of the prism 220, the light path with respect to the Y-axis may be also changed, and thus the first ray L1 and the third ray L3 may be split in the diagonal direction and imaged. In addition, because the second ray L2 and the third ray L3 may be incident spaced apart from each other in the X-axis direction and the Y-axis direction and pass through different inclined faces 224 and 223 of the prism 220, the light path with respect to the Y-axis may be also changed, and thus the second ray L2 and the third ray L3 may be split in the diagonal direction and imaged. However, because the first ray L1 and the second ray L2 are also spaced apart from each other in the X-axis direction, a direction (the diagonal direction of 45 degrees) between the imaging location of the first ray L1 and the imaging location of the third ray L3 and a direction between the imaging location of the second light ray L2 and the imaging location of the third light ray L3 may be different.

According to FIG. 5B, the fourth ray L4 and the fifth ray L5 may not be spaced apart from each other in the X-axis direction, and the fourth ray L4 and a sixth ray L6 may be spaced apart from each other by a certain distance in the X-axis direction. According to FIG. 5C, the fourth ray L4, the fifth ray L5, and the sixth ray L6 may be spaced apart from each other by a certain distance in the Y-axis direction, and may be inclined at an angle of −4 degrees in a counterclockwise direction by using the X-axis as the rotation axis and incident on the lens 230. The fourth ray L4, the fifth ray L5, and the sixth ray L6 may be reflected from the same object. In FIG. 5D, the fourth ray L4 and the fifth ray L5 may pass through one inclined face 223 of the prism 220, and the sixth ray L6 may pass through the other inclined face 224 of the prism 220. Referring to FIG. 6, the fourth ray L4 and the fifth ray L5 reflected from the same object may be imaged at the same location, and the fourth light ray L4 and the sixth light ray L6 may be split and imaged at different locations. In this example, the fourth light ray L4 and the sixth light ray L6 may be split in the diagonal direction. The fourth ray L4 and the fifth ray L5 may be incident spaced apart from each other in the Y-axis direction and pass through the same inclined face 223 of the prism 220, and thus there is no factor in the change in the light path with respect to the X-axis, and a distance between the fourth ray L4 and the fifth ray L5 spaced apart from each other in the Y-axis direction may be close enough so that the fourth ray L4 and the fifth ray L5 may be imaged to almost overlap each other. However, embodiments are not limited thereto, and the fourth ray L4 and the fifth ray L5 may be split in the Y-axis direction and imaged. For example, when the distance between the fourth ray L4 and the fifth ray L5 spaced apart from each other in the Y-axis direction is greater than or equal to a certain distance, the fourth ray L4 and the fifth ray L5 may be split in the Y-axis direction and imaged. The fourth ray L4 and the sixth ray L6 may be incident spaced apart from each other in the X-axis direction and the Y-axis direction, and pass through different inclined faces 223 and 224 of the prism 220, so that the fourth ray L4 and the sixth ray L6 may be split in the diagonal direction and imaged.

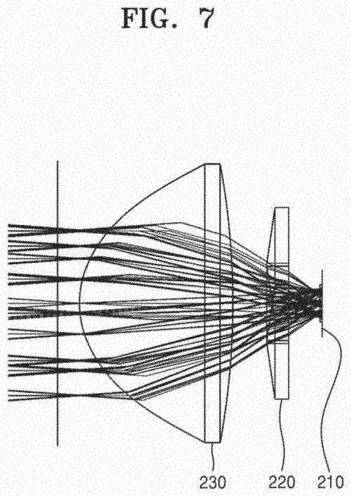

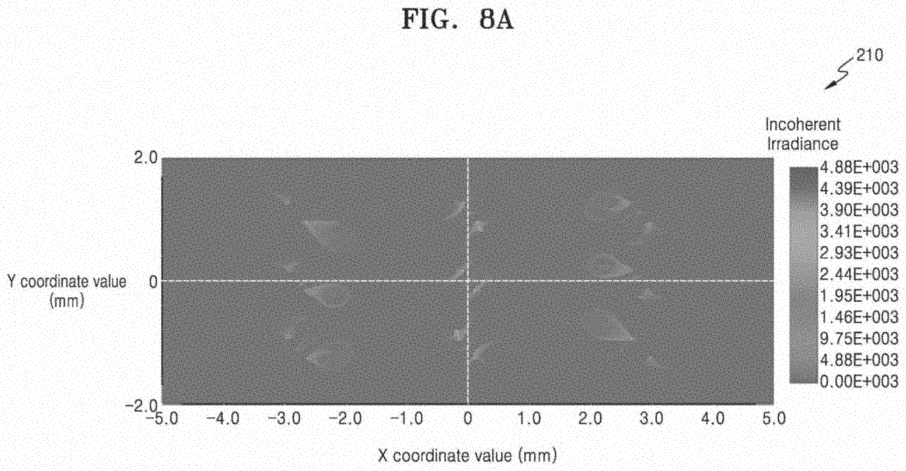

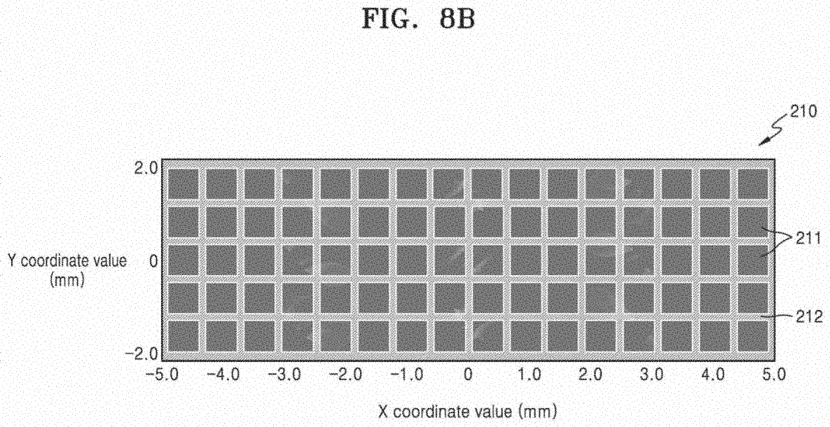

FIG. 7 is a cross-sectional view illustrating a light path when 9 representative points are imaged in the LiDAR device 10 according to an example embodiment. FIG. 8A is a graph illustrating a result of splitting and forming 9 representative points on the light detection array 210 in FIG. 7, and FIG. 8B illustrates the dead zone 212 overlapped on the graph of FIG. 8A.

Referring to FIGS. 7 to 8A, the light detection array 210 may be an APD array including a plurality of APDs as a 16*5 array, a FoV may cover a region of 20° in the horizontal direction and 8° in the vertical direction in a region of the light detection array 210 of 9.6 mm wide and 3.0 mm long, and the prism 220 may be rotated by −45 degrees with respect to the optical axis as shown in FIG. 5A. According to FIG. 8A, the 9 representative points may be split into at least two or more points in a direction of about 45 degrees and imaged. The incoherent irradiance is a signal magnitude of a detected region, and may indicate relative brightness. However, depending on the incident light, the 9 representative points may be split in a direction of 30 degrees to 60 degrees and imaged, but embodiments are not limited thereto. In FIG. 8B, the plurality of light detection elements 211 and the dead zone 212 disposed therebetween that are included in the light detection array 210 are indicated in the result of FIG. 8A. Here, pitches between the plurality of light detection elements 211 is 600 μm, and a line width of the dead zone 212 is 150 μm. Because representative points may be split into at least two or more points in a diagonal direction and imaged, light may be dispersed and received in at least two of the plurality of light detection elements 211. If the prism 220 is not disposed, 3 representative points from among the 9 representative points may be imaged along the X=0 line, and a part with X=0 corresponds to the dead zone 212, and thus light may not be received by the light detection array 210. The LiDAR device 10 according to an example embodiment may include the prism 220 splitting the light, and accordingly, the light focused on the dead zone 212 may be split, and thus the light may be dispersed and received by at least two of the plurality of light detection elements 211. The LiDAR device 10 according to an example embodiment may reduce an influence by the dead zone 212 and may have high light reception efficiency. For example, the lowest light reception efficiency may be increased to about 30% or more with respect to the FOV, and preferably, may be increased to about 35% to about 40% or more.

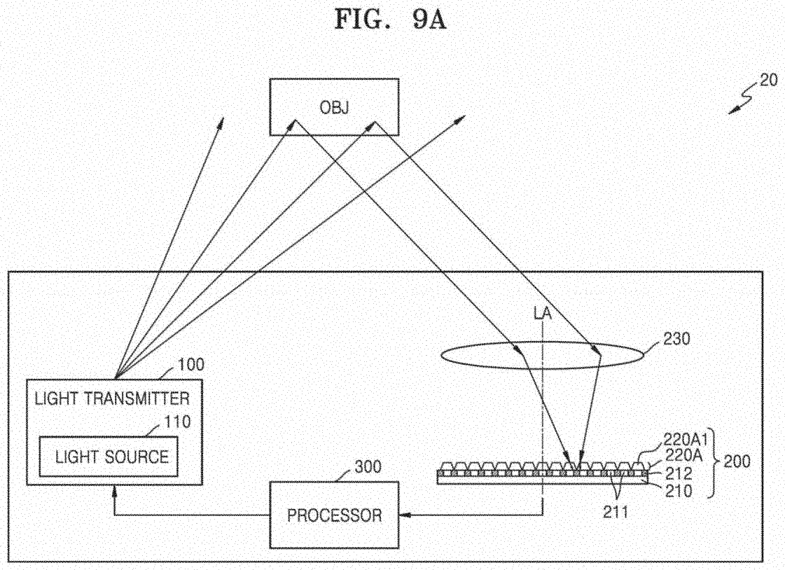

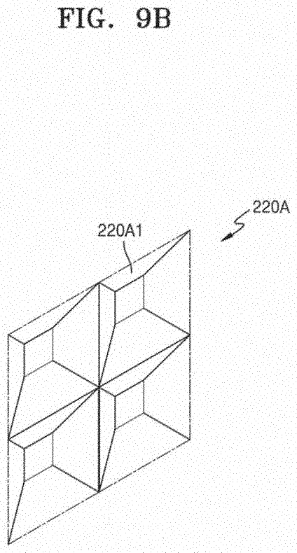

FIG. 9A is a diagram conceptually illustrating a configuration of a LiDAR device 20 and a path of light output from the LiDAR device 20 according to an example embodiment. FIG. 9B is a diagram illustrating a schematic configuration of a prism array 220A of the LiDAR device 20 according to an example embodiment.

Referring to FIGS. 9A and 9B, the prism 220 of the LiDAR device 20 according to an example embodiment may be the prism array 220A including a plurality of prism elements 220A1, and the plurality of prism elements 220A1 may correspond one-to-one to the plurality of light detection elements 211.

At least one of the plurality of prism elements 220A1 may have a shape of a frustum of a quadrangular pyramid cut along a plane perpendicular to the light axis of the lens 230. The prism element 220A1 having the shape of the frustum of the quadrangular pyramid may have inclined faces in four directions. A first face that is a plane formed by cutting a plane perpendicular to the light axis of the prism element 220A1 may be disposed to face the lens 230, and may be perpendicular to the optical axis. A bottom surface of the frustum of the quadrangular pyramid may be a second face, and may be disposed in contact with the light detection array 210. The shape of a frustum of a quadrangular pyramid may be referred to as a pyramid shape in which a part including an apex is cut along the plane perpendicular to the optical axis of the lens 230. The prism element 220A1 may have a quad-prism shape. In a cross-section viewed vertically from the first face of the prism element 220A1, light may be split in a cross direction in which the four inclined faces are located.

However, the shape of the prism element 220A1 is not limited to the above example and may have various shapes. For example, the prism element 220A1 may have a bi-prism shape. A bi-prism may also be cut along the plane perpendicular to the light axis of the lens 230. In this example, the light may be split in a direction in which inclination directions of two inclined faces of the bi-prism are projected onto the plane perpendicular to the light axis.

The prism array 220A may be disposed to have a rotational phase of 0 degree to 90 degrees by using the optical axis (Z-axis) as a rotation axis. For example, the prism array 220A may be disposed to have a rotational phase of 30 degree to 60 degrees by using the optical axis as the rotation axis. The rotational phase may be appropriately selected in consideration of light reception efficiency, etc.

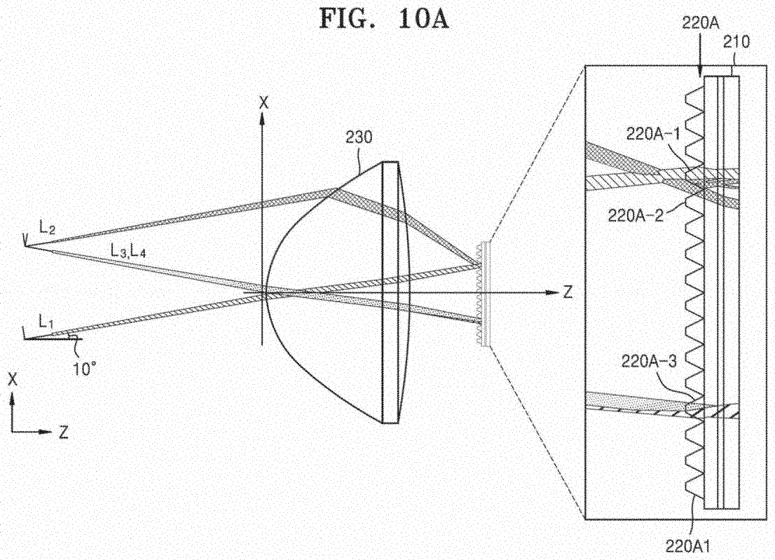

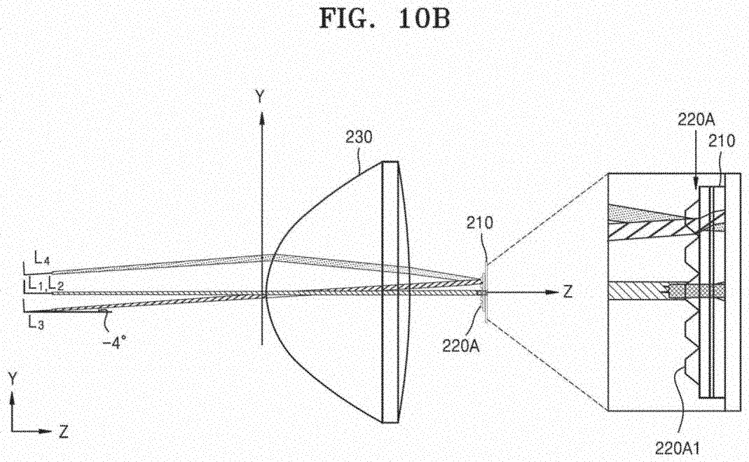

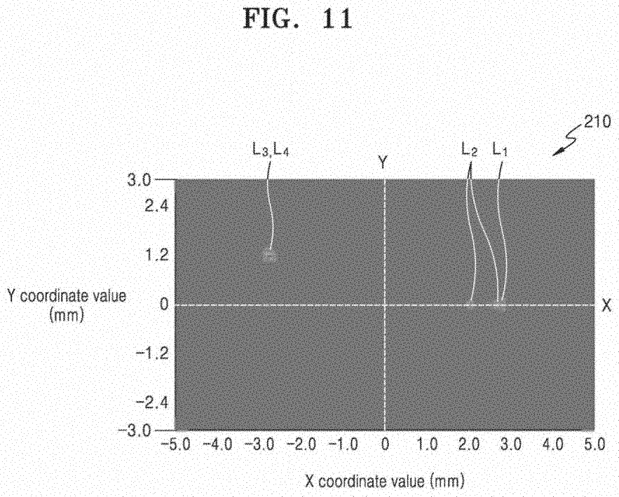

FIG. 10A is a plan view illustrating light paths of the first to fourth rays L1 to L4 in the LiDAR device 20 according to an example embodiment. FIG. 10B is a cross-sectional view illustrating light paths of the first to fourth rays L1 to L4 of FIG. 10A. FIG. 11 is a graph illustrating imaging locations of the first to fourth rays L1 to L4 incident on the light detection array 210 in the example of FIGS. 10A and 10B.

According to FIG. 10A, the prism included in the LiDAR device 20 according to an example embodiment may be the prism array 220A including the plurality of prism elements 220A1, and each of the plurality of prism elements 220A1 may have a shape of a frustum of a quadrangular pyramid. The plurality of prism elements 220A1 may correspond one-to-one to the plurality of light detection elements 211 and each of the plurality of prism elements 220A1 may be disposed in contact with corresponding one of the plurality of light detection elements 211. In a cross-section viewed vertically from a first face of the prism element 220A1, a cross direction in which four inclined surfaces are located may be an X-axis direction and a Y-axis direction.

For example, each of the plurality of prism elements 220A1 may have a thickness of about 0.4 mm, the length of one square side of a second face of the frustum of the quadrangular pyramid may be about 0.6 mm, and the length of one side of the first face of the quadrangular truncated pyramid may be about 0.2 mm. The refractive index of the prism array 220A may be about 1.78, an optical adhesive having a thickness of about 10 μm to about 100 μm and a refractive index of about 1.54 may be disposed between the prism array 220A and the light detection array 210 to bond the prism array 220A and the light detection array 210, the thickness of the light detection array 210 may be about 0.1 mm to about 0.3 mm, and the prism array 220A may include indium phosphide (InP) having a refractive index of about 3.2.

According to FIG. 10A, the first ray L1 and the second ray L2 may be spaced apart from each other by a certain distance in the X-axis direction, and may be inclined at an angle of 10 degrees in a counterclockwise direction by using the Y-axis direction as a rotation axis and incident on the lens 230. According to FIG. 10B, the first ray L1 and the second ray L2 may not be spaced apart from each other in the Y-axis direction. The first ray L1 and the second ray L2 may be reflected from the same object. In FIG. 10A, the first ray L1 and a first part of the second ray L2 may pass through a first prism element 220A-1 of the prism array 220A, and a second part of the second ray L2 may pass through a second prism element 220A-2. Referring to FIG. 11, because the first ray L1 and the first part of the second ray L2 passes through the same first prism element 220A-1, the first ray L1 and the first part of the second ray L2 may be imaged at the same location, and because the second part of the second ray L2 passes through the second prism element 220A-2, the second part of the second ray L2 may be imaged at a different location from that of the first ray L1. Because each part of the second ray L2 passes through the at least one prism element 220A1, the second ray L2 may be split (dispersed) and imaged on at least two different locations. However, embodiments are not limited thereto. Even though a ray passes through one prism element 220A1, since the ray passes through the first face and four inclined faces of the prism element 220A1, the ray may be imaged on two different locations. Because the first ray L1 and the second part of the second ray L2 is incident spaced apart from each other in the X-axis and is incident on the different prism elements 220A-1 and 220A-2 on the same Y-axis, respectively, the first ray L1 and the second part of the second ray L2 may be spaced apart from each other in the X-axis direction and imaged on two different locations as shown in FIG. 11.

According to FIG. 10A, the third ray L3 and the fourth ray L4 may not be spaced apart from each other in the X-axis direction. According to FIG. 10B, the third ray L3 and the fourth ray L4 may be spaced apart from each other by a certain distance in the Y-axis direction, inclined at an angle of −4 degrees in a counterclockwise direction by using the X-axis direction as the rotation axis and incident on the prism array 220A. The third ray L3 and the fourth ray L4 may be reflected from the same object. According to FIGS. 10A and 10B, the third ray L3 and the fourth ray L4 may pass through the same third prism element 220A-3, so that the third ray L3 and the fourth ray L4 may be imaged as almost one point in the light detection array 210. However, embodiments are not limited thereto. When a distance between the third ray L3 and the fourth ray L4 spaced apart from each other is increased, the third ray L3 and the fourth ray L4 may pass through different prism elements 220A1 and be split. According to example embodiments, imaging locations of the third ray L3 and the fourth ray L4, when there is no prism array 220A, are between the two prism elements 220A1, for example, when the imaging locations are within the dead zone 212, the third ray L3 and the fourth ray L4 may pass through different prism elements 220A1 and be split.

When the prism array 220A is disposed in correspondence to the light detection array 210 as described above, the light reflected from the object may be split and imaged on an OPA. In this example, light to be incident on the dead zone 212 may be incident on the light detection element 211, thereby reducing or preventing a decrease in light reception efficiency.

In the LiDAR device 20 according to an example embodiment described with reference to FIGS. 10A to 11, the prism array 220A may be disposed at 0 degree with respect to the light axis so that light may be split in a cross direction (X-axis and Y-axis directions). However, embodiments are not limited thereto. When the prism array 220A is disposed at −45 degrees with respect to the light axis, light may be split in a cross direction including a diagonal direction of 45 degrees (a diagonal line forming 45 degrees with the X-axis and Y-axis).

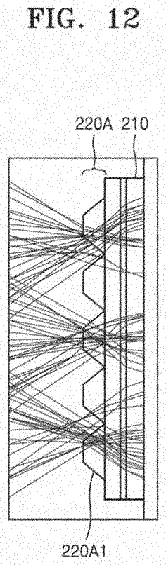

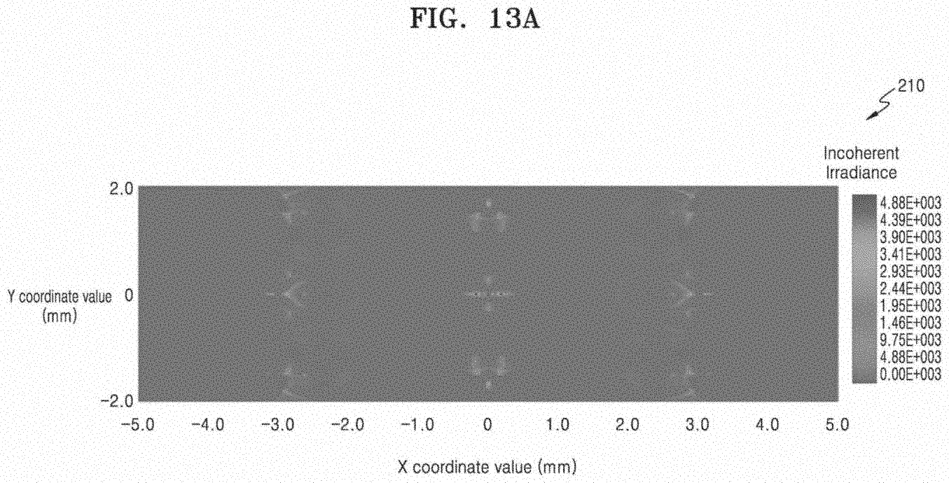

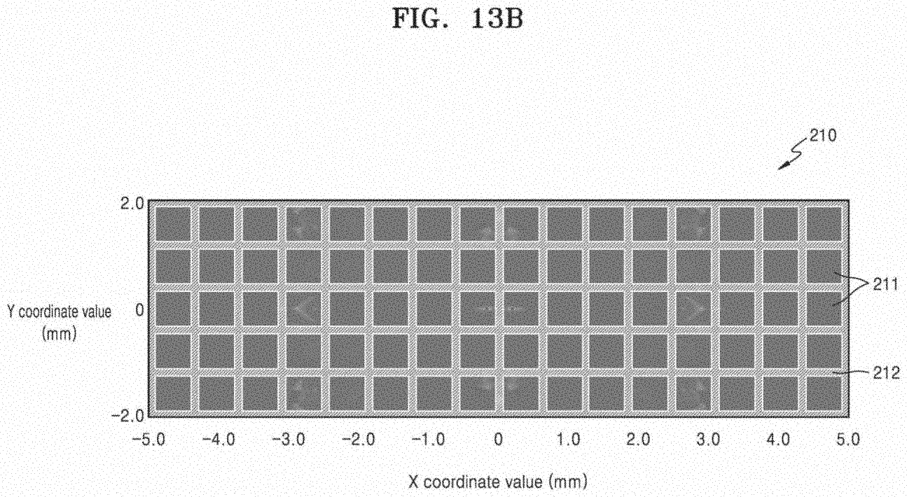

FIG. 12 is a cross-sectional view illustrating a light path when 9 representative points are imaged in the LiDAR device 20 according to an example embodiment. FIG. 13A is a graph illustrating a result of splitting and forming 9 representative points on the light detection array 210 in FIG. 12, and FIG. 13B illustrates the dead zone 212 overlapped on the graph of FIG. 13A.

Referring to FIGS. 12 and 13A, the light detection array 210 may be an APD array including a plurality of APDs as a 16*5 array, a FoV may cover a region of 20° in the horizontal direction and 8° in the vertical direction in a region of the light detection array 210 of 9.6 mm wide and 3.0 mm long, and the prism 220 may be the prism array 220A including the plurality of prism elements 220A1 corresponding one-to-one to the plurality of APDs. The plurality of prism elements 220A1 may have a frustum of a quadrangular pyramid or a pyramid shape cut along a plane perpendicular to the light axis. According to FIG. 13A, the 9 representative points may be split into at least two points in a cross direction including the X-axis and the Y-axis and imaged. However, the 9 representative points may be split in different directions according to the incident light, and embodiments are not limited thereto. In FIG. 13B, the plurality of light detection elements 211 and the dead zone 212 disposed therebetween that are included in the light detection array 210 are indicated in the result of FIG. 13A. Here, pitches between the plurality of light detection elements 211 is 600 μm, and a line width of the dead zone 212 is 150 μm. Because representative points may be split into at least two or more points in a diagonal direction and imaged, light may be dispersed and received in at least two of the plurality of light detection elements 211. When the prism array 220A is not disposed, 3 representative points from among the 9 representative points may be imaged along the X=0 line, and a part with X=0 corresponds to the dead zone 212, and thus light may not be received by the light detection array 210. The LiDAR device 20 according to an example embodiment may include the prism array 220A splitting the light, thereby splitting the light to be imaged on the dead zone 212, and accordingly, the light may be dispersed and received by at least two of the plurality of light detection elements 211. The LiDAR device 20 according to an example embodiment may reduce an influence by the dead zone 212 and may have high light reception efficiency. For example, the lowest light reception efficiency may be increased to about 30% or more with respect to the FOV, and preferably, may be increased to about 35% to about 40% or more.

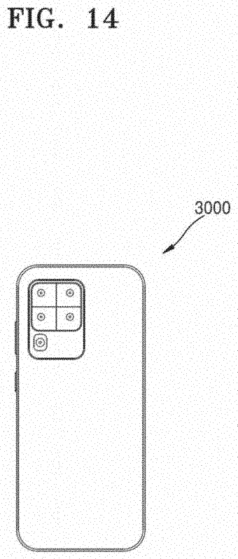

FIG. 14 is a perspective view illustrating an example of an electronic device to which the LiDAR devices 10 and 20 according to an example embodiment is applied.

Although FIG. 14 is illustrated in the form of a mobile phone or a smart phone 3000, the electronic device to which the LiDAR devices 10 and 20 are applied is not limited thereto. For example, the LiDAR devices 10 and 20 may be applied to a tablet or a smart tablet, a laptop computer, a television or a smart television.

In addition, the LiDAR devices 10 and 20 according to an example embodiment may be applied to an autonomous driving device.

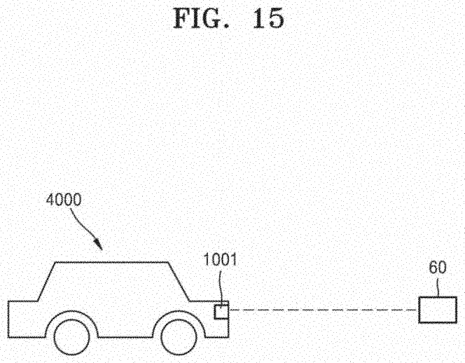

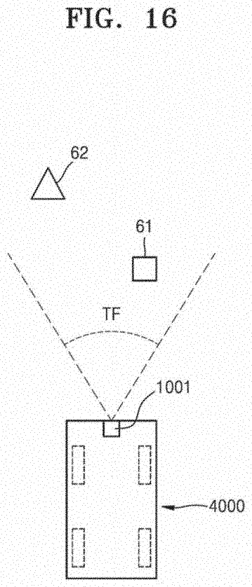

FIGS. 15 and 16 are conceptual diagrams illustrating examples in which a LiDAR device 1001 according to an example embodiment is applied to a vehicle 4000, and are a side view and a plan view, respectively.

Referring to FIG. 15, the LiDAR device 1001 may be applied to the vehicle 4000, and information about an object 60 may be obtained by using the LiDAR device 1001. The LiDAR devices 10 and 20 described with reference to FIGS. 1 to 13B may be employed as the LiDAR device 1001. The LiDAR device 1001 may use a TOF method to obtain the information about the object 60. The vehicle 4000 may be a vehicle having an autonomous driving function. When an object is present in the target region and light reflected from the object is detected, digital-scanning of the target region may be started and information about the object may be analyzed. Using the LiDAR device 1001, an object or a person located in a direction in which the vehicle 4000 is moving, i.e., the object 60, may be detected and a distance to the object 60 may be measured using a time difference between a transmitted signal and a detected signal. In addition, as shown in FIG. 16, information about an object 61 in a near distance and an object 62 in a far distance within a target region TF may be obtained.

FIGS. 15 and 16 illustrate that the LiDAR device 1001 is to be applied to a car, but embodiments are not limited thereto. The LiDAR device 1001 may be applied to flying objects such as a drone, mobile devices, small-sized walking means (e.g., a bicycle, a motorcycle, a stroller, a skateboard, etc.), a robot, a human/animal assistance means (e.g., a cane, a helmet, ornaments, clothing, a watch, a bag, etc.), Internet-of-Things (IoT) devices/systems, security devices/systems, etc.

The LiDAR device according to an example embodiment may split incoming light including a prism, and disperse and receive the light in pixels, thereby increasing light reception efficiency.

The LiDAR device according to an example embodiment may include a prism array to split incoming light, and disperse and receive the light in pixels, thereby increasing light reception efficiency.

The LiDAR device according to an example embodiment may disperse and receive light, thereby reducing an influence by a dead zone.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. A laser induced light detection and ranging (LiDAR) device comprising:
a light source configured to output light;
a light detection array comprising a plurality of light detection elements configured to receive light that is output from the light source and reflected by an object and to convert the light into a corresponding electric signal;
a lens configured to focus the light reflected by the object on the plurality of light detection elements;
a prism provided between the lens and the light detection array, the prism being configured to split the light output from the lens and direct the light to be incident on the light detection array; and
a processor configured to process the electrical signal, and obtain a time of flight (TOF) of the received light based on the processed electrical signal.

2. The LiDAR device of claim 1, wherein the prism is a bi-prism or quad-prism.

3. The LiDAR device of claim 2, wherein the prism is a hexahedron having at least one face comprising a trapezoid shape.

4. The LiDAR device of claim 3, wherein two angles of a bottom side of the trapezoid shape are 1 degree to 60 degrees, and
wherein a height of the prism is 0.1 mm to 100 mm.

5. The LiDAR device of claim 1, wherein the prism is spaced apart from the light detection array.

6. The LiDAR device of claim 1, wherein the prism comprises at least two prisms, and
wherein the at least two prisms form a bi-prism or a quad prism.

7. The LiDAR device of claim 1, wherein the prism has a rotational phase of 0 degree to 90 degrees with respect to an optical axis of the lens.

8. The LiDAR device of claim 1, wherein the prism has a rotational phase of 30 degrees to 60 degrees with respect to an optical axis of the lens.

9. The LiDAR device of claim 1, wherein the light reflected by the object is received by at least two of the plurality of light detection elements.

10. The LiDAR device of claim 1, wherein each of a first light detection element and a second light detection element adjacent to each other from among the plurality of light detection elements is configured to receive a part of the split light, and
wherein the processor is further configured to add electrical signals output by the first light detection element and the second light detection element.

11. The LiDAR device of claim 1, wherein the light detection array comprises a first column and a second column adjacent to each other,
wherein at least one light detection element provided in each of the first column and the second column is configured to receive a part of the split light, and
wherein the processor is further configured to add electrical signals output by the at least one light detection element disposed in each of the first column and the second column.

12. The LiDAR device of claim 1, wherein the plurality of light detection elements comprises at least one of an avalanche photodiode (APD) or a single photon avalanche diode (SPAD).

13. The LiDAR device of claim 1, wherein the plurality of light detection elements of the light detection array are provided in an N*M array, where N and M are an integer greater than or equal to 1.

14. The LiDAR device of claim 1, wherein pitches between adjacent light detection elements among the plurality of light detection elements of the light detection array are 50 μm to 2,000 μm, and
wherein an area of a dead zone in the light detection array is 5% to 40% of an area of the light detection array.

15. The LiDAR device of claim 1, wherein a lowest light reception efficiency of the LiDAR device is greater than or equal to 30%.

16. The LiDAR device of claim 1, wherein the prism is a prism array comprising a plurality of prism elements, and
wherein the plurality of prism elements correspond one-to-one to the plurality of light detection elements.

17. The LiDAR device of claim 16, wherein at least one of the plurality of prism elements has a shape of a frustum of a quadrangular pyramid cut along a plane perpendicular to an optical axis of the lens.

18. The LiDAR device of claim 16, wherein at least one of the plurality of prism elements has an rotational phase of 30 degrees to 60 degrees with respect to an optical axis of the lens.

19. The LiDAR device of claim 16, wherein the prism array contacts the light detection array.

20. An electronic device comprising a laser induced light detection and ranging (LiDAR) device, the LiDAR device comprising:
a light source configured to output light;
a light detection array comprising a plurality of light detection elements configured to receive light that is output from the light source and reflected by an object and to convert the light into a corresponding electric signal;
a lens configured to focus the light reflected by the object on the plurality of light detection elements;
a prism provided between the lens and the light detection array, the prism being configured to split the light output from the lens and direct the light to be incident on the light detection array; and
a processor configured to process the electrical signal, and obtain a time of flight (TOF) of the received light based on the processed electrical signal.
